(19) United States
(12) Patent Application Publication
(10) Pub. No.: US 2012/0178076 A1
(43) Pub. Date: Jul. 12, 2012

(54) MAGNETIC RESONANCE AND NON-MAGNETIC RESONANCE ANALYSIS

(76) Inventors: Hiroyuki FUJITA, Highland Heights, OH (US); John L. Patrick, Chagrin Falls, OH (US)

(21) Appl. No.: 12/986,442

(22) Filed: Jan. 7, 2011

(51) Int. Cl. A01N 1/02; G01R 33/48

(52) U.S. Cl. 435/1.2; 435/284.1; 324/309

(57) ABSTRACT

In one embodiment, a hypothermic pulsatile perfusion (HPP) apparatus is described. The example HPP includes a chamber configured to house an object (e.g., kidney, liver, heart, skin graft) to be transplanted. The example HPP may include a nuclear magnetic resonance (NMR) element(s) (e.g., coil) configured to facilitate performing a first (e.g., magnetic resonance (MR) based) analysis of the object using a first set of frequencies. The example HPP may also include a spectrum element (e.g., optical probe) configured to facilitate performing a second (e.g., non-MR based) analysis of the object using a second, different set of frequencies. The HPP apparatus is constructed from MR compatible, non-ferromagnetic materials. In one embodiment, a combination MR/non-MR apparatus may apply MR and non-MR electromagnetic energy to an object housed in the HPP apparatus.

### BACKGROUND

There are more patients who are waiting for organ transplants than there are organs available. Therefore, every potential donor organ is precious. There are some tools available to pathologists, surgeons, and others involved in organ transplants. However, these tools have traditionally been invasive (e.g., biopsy), subjective (e.g., visual assessment, olfactory assessment), and/or may have required substantial equipment (e.g., conventional x-ray apparatus, conventional magnetic resonance imaging (MRI) apparatus). Sometimes the tools have produced either false negatives or positives. See, for example, Stowe et al., Intrarenal Haemodynamics During Hypothermic Perfusion of Cadaver Kidneys, Proc. Of European Renal Association, vol. 10_{—}51.1973, that reports on pressure-flow measurements during perfusion yielding false positives and negatives. Additionally, these tools may not have been suitable for use in an operating room, transplant ward, or location at which an organ may be harvested. Consider histopathology, which requires cutting out a tissue sample, fixing the sample in a medium, staining the tissue, and then interpreting the result. These steps may consume more time (e.g., hours, days) than can be tolerated for a candidate transplant organ. Consider also microdialysis, which requires inserting a needle into the tissue. Once again, the invasiveness and time requirements may make microdialysis unsuitable for the transplant environment.

### BRIEF DESCRIPTION OF THE DRAWINGS

The accompanying drawings, which are incorporated in and constitute a part of the specification, illustrate various example systems, methods, and other example embodiments of various aspects of the invention. It will be appreciated that the illustrated element boundaries (e.g., boxes, groups of boxes, or other shapes) in the figures represent one example of the boundaries. One of ordinary skill in the art will appreciate that in some examples one element may be designed as multiple elements or that multiple elements may be designed as one element. In some examples, an element shown as an internal component of another element may be implemented as an external component and vice versa. Furthermore, elements may not be drawn to scale.

FIG. 1 illustrates an embodiment of a hypothermic pulsatile perfusion (HPP) apparatus that includes analytic elements that operate in two different electromagnetic spectra.

FIG. 2 illustrates an embodiment of an HPP apparatus configured with an optical probe.

FIG. 3 illustrates an embodiment of an HPP apparatus configured with analytic element test elements.

FIG. 4 illustrates an embodiment of a perfusion apparatus configured with optical elements.

FIG. 5 illustrates an embodiment of a perfusion apparatus configured with optical elements, a camera, a communication apparatus, and a microscope.

FIG. 6 illustrates an embodiment of a perfusion apparatus configured with optical elements and a viability logic.

FIG. 7 illustrates an embodiment of an apparatus that includes, an NMR apparatus configured to operate in an NMR spectrum, an optical apparatus configured to operate in a non-NMR spectrum, spectra receiving apparatus configured to receive spectral data in response to the NMR apparatus and/or the optical apparatus applying electromagnetic energy to an object positioned in a perfusion apparatus, and a data logic configured to provide object viability data based on the spectral data.

FIG. 8 illustrates an embodiment of an apparatus like that illustrated in FIG. 7 that also includes a camera and a microscope.

FIG. 9 illustrates an embodiment of an apparatus that includes optical apparatus configured to perform an optical-based analysis of an organ positioned in a pulsatile perfusion apparatus.

FIG. 10 illustrates an embodiment of an apparatus like that illustrated in FIG. 9 that also includes a camera and a microscope.

FIG. 11 illustrates a method associated with providing organ viability data from spectral data acquired from an organ that is housed in a pulsatile perfusion apparatus, where the organ is analyzed using both an MR based approach and a non-MR based approach.

FIG. 12 illustrates a method associated with providing organ viability data from data acquired from an organ that is housed in a pulsatile perfusion apparatus, where the organ is analyzed using both an MR based approach and a photographic approach.

FIG. 13 illustrates a method associated with providing organ viability data from spectral and/or photographic data acquired from an organ that is housed in a pulsatile perfusion apparatus, where the organ is analyzed using one or more of, a non-MR technique, and a photographic technique.

### DETAILED DESCRIPTION

Example apparatuses provide tools for quantitatively, objectively, and non-invasively assessing the viability of organs to be transplanted. Tools for non-invasively maintaining and assessing the viability of organs to be transplanted would facilitate increasing the odds that a donor organ will ultimately become a transplanted organ (e.g., kidney, heart, tissue). More generally, example apparatuses provide tools for quantitatively, objectively, and non-invasively analyzing objects (e.g., organs, tissues) in an MR compatible perfusion apparatus using a combination of MR-based and non-MR-based approaches.

Light-based medical apparatus have a long and important place in medicine. For example, optical lenses provided insights into the microscopic world. Similarly, medical apparatuses based on other types of electromagnetic energy have also been important to medicine. For example, optical techniques including, but not limited to, optical coherence tomography (OCT), some spectroscopy, and photography, have provided additional insights. Spectroscopic techniques include, but are not limited to, reflectance, fluorescence, laser induced fluorescence (LIF), infrared absorption, and Raman.

Bagnato et al., New Perspectives For Optical Techniques In Diagnostic And Treatment Of Hepatic Diseases, Acta Cirurgica Brasileira—Vol. 25 (2) 2010, pg 214-216 reviews different optical techniques that may be useful in liver transplantation. Bagnato reports how “spectroscopic signals can indicate biochemical changes [that] . . . may precede morphological changes observed in histology.” Bagnato also reports that the existence of a good correlation between Steatosis Fluorescence Factor (SFF) is directly correlated with the quantity of fat in kidney tissue. The degree of steatosis can be determined once the amplitude of fluorescence is determined. Thus, useful optical techniques have been demonstrated in organs (e.g., liver). “Most important”, Bagnato notes “is the fact that the information provided by spectroscopy is quantitative.” This quantitative data representing, for example, mitochondrial function and cellular adenosine triphosphate (ATP) content, may be analyzed to indicate metabolic status, which may be relevant to organ viability.

Raman, et al., A Non-Contact Method and Instrumentation To Monitor Renal Ischemia And Reperfusion With Optical Spectroscopy, Optics Express 894, January 2009, Vol. 17, No. 2, also report on organ analysis using optical spectra. Raman describes how nicotinemide adenine dinucleotide (NADH) autofluorescence is useful as an in vivo optical signature for monitoring tissue metabolism. NADH is a flavin and an electron carrier in the transport chain. The concentration of NADH depends, at least in part, on metabolic state. Conventional spectroscopic techniques may have been contact based. However, contacting an organ to acquire information for analyzing the organ viability may impact the data that is acquired at the contact site. For example, pressure applied by a contact probe can alter local hemodynamics and influence local metabolic activity by interfering with perfusion and saturation. Additionally, contact techniques may have interrogated an area of an organ that is too small to be relevant for overall organ viability analysis. Therefore, a non-contact technique may facilitate acquiring superior organ viability data.

Raman reports on a non-contact method that monitors kidney response to ischemia and reperfusion using NADH autofluorescence. The Raman technique imaged the entire exposed organ surface under 355 nm excitation. Analyzing a large surface area facilitated acquiring both numerous local measurements and overall average measurements. These two types of measurements may be relevant to assessing overall organ viability.

Raman describes one issue with their handheld approach, that having a fixed repeatable position with respect to organ analysis location “cannot be expected using a portable non-contact probe.” Raman reports how “the distance between the fiber tip and kidney surface, as well as the angle between the illumination direction and the kidney surface can change and thus significantly affect the measured signal intensity.” Since organ viability may need to be assessed periodically and/or substantially constantly after harvest and before transplantation, acquiring consistent results may be important, rendering the Raman system sub-optimal. In one embodiment, example apparatuses and methods facilitate maintaining a more constant relationship between optical analysis tools like the Raman spectroscopy probe and the organ.

Raman describes that another issue with spectroscopy is that tissue hydration status can change. A change in the hydration of the tissue may affect the scattering properties of the tissue and the amount of excitation light that is reflected. This is especially a concern at the air-tissue interface. In one embodiment, example apparatuses and methods facilitate maintaining a more constant tissue hydration status by holding the organ in a liquid solution. Holding the organ in a liquid solution may also remove the air-tissue interface.

Gorbach et al., Assessment of Cadaveric Organ Viability During Pulsatile Perfusion Using Infrared Imaging, Transplantation, 2009 Apr. 27; 87(8): 1163-1166, describe experiments involving infrared (IR) measurements of kidneys being perfused. The experiments were designed to investigate “IR imaging during pulsatile perfusion as a means for precise organ assessment.” The Gorbach IR imaging was based on two-dimensional mapping of temperature differences by detecting natural emissions from tissue that are warmer or cooler than their surrounding structures and environment. Gorbach imaged the local temperature gradients in perfused kidneys by passively detecting the IR emissions from the kidneys.

Gorbach reports that IR measurements have a “strong direct correlation with measured resistance within the kidney”. Gorbach also reports that “there was an indirect correlation with flow.” Thus, Gorbach describes how IR imaging correlates with the generally accepted conventional perfusion measurements of flow and resistance. Additionally, Gorbach notes that the data are objective and quantitative. Objective, quantitative data may facilitate assessing organ viability.

Described herein are example apparatuses and methods associated with a dedicated apparatus configured to perform MR and/or non-MR electromagnetic analyses of an object (e.g., tissue, organ) housed in an HPP apparatus configured with at least one MR specific element (e.g., coil, magnet) and/or at least one non-MR spectrum (e.g., x-ray, fluoroscopy, OCT, optical spectroscopy, photographic, IR imaging) element. Organ viability may be determined based on analyzing both the MR and non-MR data. Similarly, tissue viability may be determined based on analyzing both the MR and non-MR data.

More generally, described herein are example apparatuses and methods associated with improving workflow and accuracy in analyzing an object. Example apparatuses integrate one or more MR elements (e.g., coil, magnet) into a holding container. Additionally, and/or alternatively, example apparatuses also integrate one or more non-MR elements (e.g., optical probe) into the holding container. Example dedicated apparatuses are configured to work with the integrated containers to perform one and/or multi-nucleus NMR (e.g., ¹H, ¹³C, ²³NA, and ³¹P) in a more relevant time frame. Example dedicated apparatuses are also configured to work with the integrated containers to perform, for example, digital radiography. In one example, an apparatus may include a communication apparatus configured to provide viability data, photographs, radiographs, or other imagery. The data may be acquired at one site (e.g., harvest location), and provided to another site (e.g., potential transplant site, transplant clearing house). This facilitates having remote personnel (e.g., surgeon, pathologist, radiologist) who may be more trained in organ viability analysis examine the organ before it is transported. The analysis may guide the remote personnel to recommend a recipient based on factors including the likelihood that the organ will survive transports of different lengths. In one example, the communication apparatus may be configured to produce images and data suitable for display on a receiving device like a computer, a cellular telephone, a personal digital assistant, or other handheld communication device. The combination of elements facilitates acquiring objective quantitative data upon which an organ viability determination can be made. While the kidney is referred to most frequently in this application, the apparatuses and techniques are more generally applicable. Similarly, while organs and organ transplants are referred to most frequently, the apparatus and methods are generally applicable to other objects (e.g., skin grafts) and other procedures (e.g., skin grafting).

NMR spectroscopy provides an NMR spectrum. An NMR spectrum provides information on the number and type of chemical entities in a molecule. In one embodiment, NMR spectroscopy is performed on a kidney to obtain a ³¹P spectrum from which spectral peaks can be identified. Peaks associated with PME, Pi, αATP, βATP, and NAD/H are identified. Data from which an organ viability determination can be made is then computed from the peaks. The data includes, for example, a PME/Pi ratio, and an αATP/βATP ratio. In other examples, different nuclei are examined in different organs.

Optical spectroscopy provides data in a different spectrum. Optical spectroscopy may also provide information on the number and type of chemical entities in a molecule. In one embodiment, optical spectroscopy is performed to obtain additional and/or alternative spectral data (e.g., absorption, reflection, emission, and fluorescence) from which an organ viability analysis can be made.

Digital radiography also provides alternative forms of spectral data. Digital radiography uses the imaging technology of x-rays with digital x-ray sensors. In one embodiment digital radiography is performed to obtain additional data (e.g., high resolution digital images). Not only may digital radiography equipment be highly portable, it is more forgiving of technical errors (e.g., over-exposure and under-exposure). The resulting digital images facilitate specialized processing that can be used to highlight specific information (e.g., density).

Unlike the experimental and research systems that were designed to facilitate better understanding of the transplant environment and the effect of HPP modules, example systems and methods concern integrated, mobile units that interact with dedicated viability MR/non-MR equipment to achieve improved workflow. Unlike conventional systems that require numerous technicians and operator interventions (e.g., coil selection, coil placement, pulse sequence selection, chamber positioning, field clearing, optical probe placement, sample placement), example systems and methods provide simplified and optimized (e.g., “one touch”) processing.

One example system includes an organ transfer container with a sterile, disposable inner liner that positions the organ in a known orientation. The container is made from MR compatible materials (e.g., non-ferromagnetic). In one embodiment, a ¹H/³¹P coil is integrated into the container. Other embodiments may employ other coils to perform MR spectroscopy for other nuclei in other organs. Integrating the coil into the container removes at least one step from the transport/transplant workflow. For example, a technician will not have to find the appropriate coil and then position the appropriate coil in the optimal location for MR applications. In one embodiment, an optical probe (e.g., optical fiber, optical fiber bundle) is integrated into the container. Other embodiments may employ other spectrum elements (e.g., lenses, cameras, microscopes, xray generators, digital sensors) to acquire spectral data and/or photographic data from the organ. In one embodiment, the apparatus may include communication equipment configured to provide data. The data provided may include, for example, raw viability data, processed viability data, imagery, radiographs, and so on. In one embodiment, the data will be suitable for display on a receiving device like a cellular telephone with a graphic display (e.g., iPhone®), a personal computer, a tablet computer (e.g., iPad®), and so on. Being able to communicate data in this manner facilities distributing that data to different doctors and other personnel at different locations, which in turn may facilitate making better decisions concerning viability and appropriate recipients.

Having the organ in a known orientation that agrees with the coil and/or optical probe position facilitates acquiring more consistent data. Since time may be of the essence in the workflow, removing the step of positioning the coil and/or optical probe may allow a shorter workflow time which may in turn lead to more organs remaining viable. Also, since the organ, the coil, and the probe will be positioned in a known correct orientation, the potentially fatal step of having to open the container and reposition the organ for analysis will be eliminated. Once again, this may lead to more organs remaining viable.

One example system also includes a dedicated MR/non-MR apparatus configured to perform organ viability testing, to test for infectious diseases, to test for cancer, and so on. More generally, one example system involves a dedicated MR/non-MR apparatus that is configured to analyze an object housed in an MR compatible perfusion apparatus. Conventional MRI apparatuses are configured to produce a wide variety of images using a wide variety of pulse sequences. Various different MR images may be acquired using a single conventional system that can be programmed to perform a large number of pulse sequences with a large number of different parameters. While this is suitable for general purpose analytic functions, this needlessly complicates and slows down the workflow. Similarly, conventional non-MR apparatuses (e.g., digital, radiography, OCT, spectroscopy, photographic) are configured to be general purpose. Once again, while suitable for general purpose analytic functions, this ignores the opportunity to optimize positioning, spectral choices, and other factors for organ viability analysis. When a camera needs to be able to take pictures of different things under different conditions, the camera may need to be reconfigured (e.g., focal length, exposure time) for each image. However, when an example camera only needs to be able to take pictures of kidneys that will be positioned in a known way at a known distance and under known lighting conditions, the camera may not need to be reconfigured. The same holds for other non-MR equipment (e.g., OCT, optical spectroscopy).

Conventional MRS apparatuses may also be configured to analyze a wide variety of nuclei in objects of widely varying sizes. In contrast, the dedicated MR/non-MR apparatus is configured to receive the container and its integrated MR components (e.g., coil) and to apply a pre-determined pulse sequence to acquire organ viability data that is based on a finite set of nuclei that may be present in organs whose shapes and sizes vary within well known ranges. Rather than being a widely configurable general purpose device, the dedicated MR/non-MR apparatus may have a small number of pre-determined pulse sequences available for different analyses of a small number of samples. The same holds for non-MR equipment including, for example, optical spectroscopy equipment.

In one embodiment, the dedicated MR/non-MR apparatus does not need to be able to produce an image. Instead, the dedicated MR/non-MR apparatus only needs to be able to produce the relevant organ viability data including, for example, PME/Pi ratio, ATP/ADP ratio, and so on.

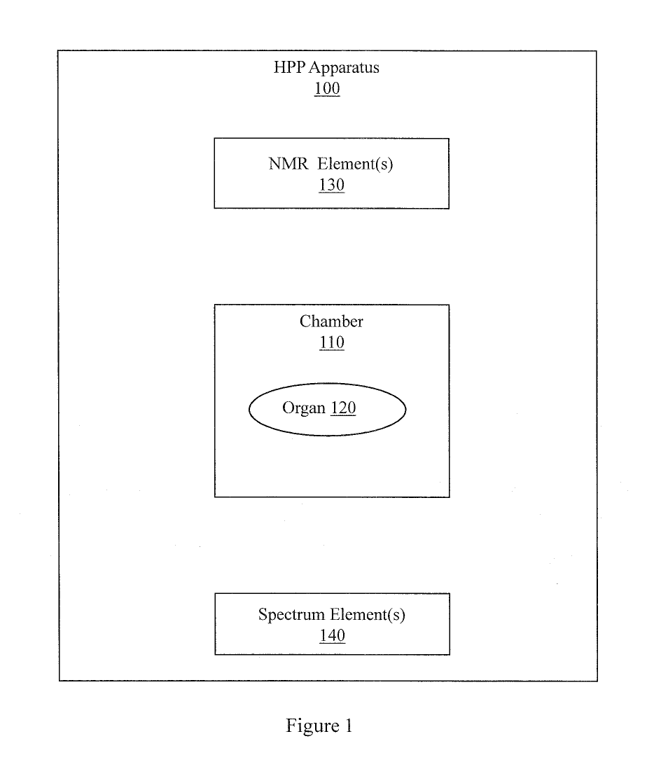

FIG. 1 illustrates an embodiment of a hypothermic pulsatile perfusion (HPP) apparatus 100 that includes analytic elements that operate in two different electromagnetic spectra. HPP 100 includes a chamber 110 that is configured to house an organ 120. The organ 120 may be, for example, a kidney, a liver, a heart, and so on. In one embodiment, chamber 110 could house something other than an organ (e.g., tissue for a skin graft).

HPP 100 includes a nuclear magnetic resonance (NMR) element(s) 130 configured to facilitate performing a first magnetic resonance (MR) based analysis of the organ 120. The MR based analysis will use frequencies that fall within a spectral bound associated with NMR. In one embodiment the frequencies will be chosen to excite specific nuclei (e.g., ³¹P). The first analysis may be, for example, magnetic resonance spectroscopy (MRS), magnetic resonance imaging (MRI), and so on.

HPP 100 also includes one or more spectrum elements 140 that are configured to facilitate performing a second, different analysis of the organ 120. The second analysis will use a set of frequencies that fall outside of the spectral bound associated with NMR. The second analysis may be, for example, optical coherence tomography (OCT), optical spectroscopy, reflectance, absorption spectroscopy, emission spectroscopy, laser-induced fluorescence, diffusive optical imaging, fluoroscopy, digital radiography, x-ray, microscopy, IR imagery, and photography. Thus, the second set of frequencies may be associated with OCT, optical spectroscopy, laser induced fluoroscopy, and so on.

In different examples, the second analysis may be an active operation or a passive operation. When the second analysis is an active operation, the second analysis may include applying electromagnetic energy to the organ 120 and receiving spectrum data in response to applying the second set of frequencies to the organ 120. The second set of frequencies may be, for example, in the far infrared range, the infrared range, the near infrared range, the visible range, the ultraviolet range, and x-ray range. When the second analysis is a passive operation, the second analysis may include taking photographs, taking photographs through a microscope, acquiring IR images, and so on. Note that HPP 100 is configured to facilitate both the MR based analysis and the non-MR (e.g., optical) based analysis. Since HPP 100 will be analyzed using the first set of frequencies (e.g., MR spectra), the HPP 100 will be constructed from MR compatible, non-ferromagnetic materials.

Recall that conventional experimental systems had issues associated with repeatable measurements. Therefore, in one example, HPP 100 may include a sterile, disposable inner liner that is configured to house the organ 120 in the chamber 110. To facilitate taking repeatable measurements, the inner liner may be configured to hold the organ 120 in a substantially constant position and orientation with respect to the NMR elements 130 and/or the spectrum elements 140. Recall also that conventional experimental systems may have had an issue with an instrument/air interface. Therefore, in one embodiment, the inner liner may be configured to house the organ 120 in a liquid solution.

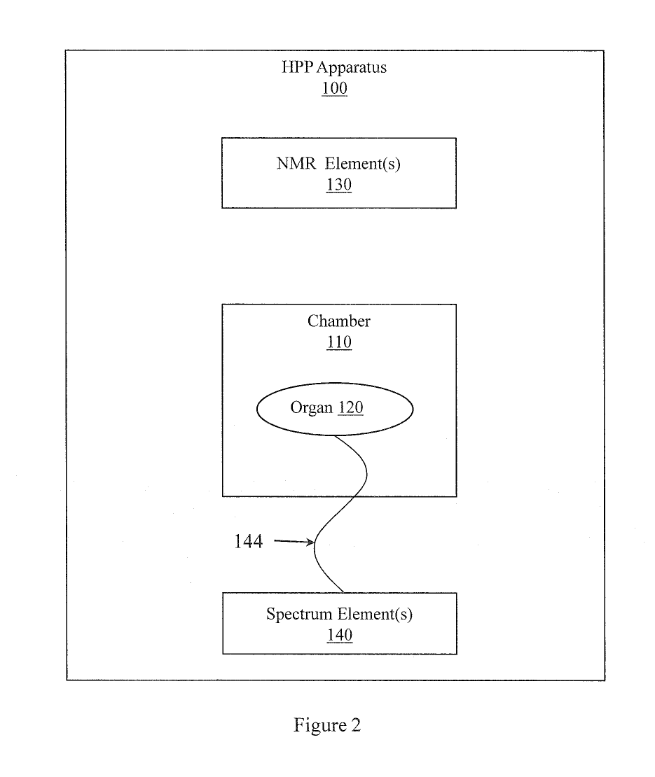

FIG. 2 illustrates an embodiment of HPP apparatus 100 that is configured with an optical probe 144. In this embodiment, the spectrum elements 140 include an optical probe 144 that is configured to detect coherent light reflected from the organ 120. The optical probe 144 may be configured to facilitate performing optical coherence tomography (OCT) and/or optical spectroscopy on the organ 120. Since the optical probe 144 will be subjected to the fields associated with MR, the optical probe 144 is constructed from MR compatible, non-ferromagnetic materials.

Recall that one issue with contact based systems was the impact on the local environment (e.g., perfusion, metabolic activity) that the contact created. Therefore, in one example, the optical probe 144 is positioned to remain at least a predetermined distance away from the organ 120.

An organ, tissue, or other object may have different characteristics at different depths. For example, the surface of a kidney may have a first characteristic that is associated with maintaining the kidney shape. However, the inside of a kidney may have a different characteristic that is associated with blood filtering. Therefore, in one example, the optical probe 144 is positioned to be placed within the organ 120 for interstitial analysis.

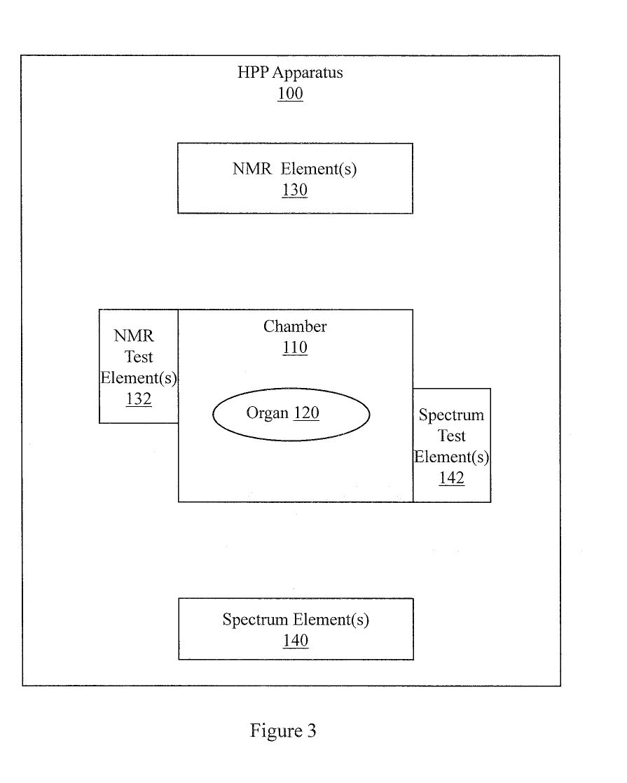

FIG. 3 illustrates an embodiment of HPP apparatus 100 that is configured with analytic element test elements. To increase confidence in NMR and non-NMR elements, test elements that should return a substantially constant measurement may be positioned in HPP apparatus 100. The test elements may include an NMR test element 132 configured to facilitate acquiring test data for assessing operation of the NMR elements 130 and a spectrum test element 142 that is configured to facilitate acquiring test data for assessing operation of the spectrum elements 140.

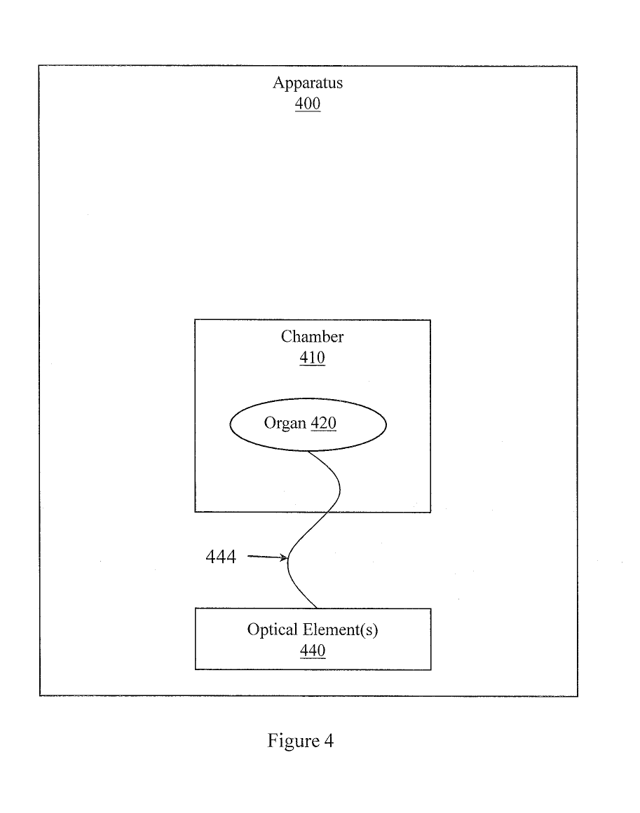

FIG. 4 illustrates an embodiment of an apparatus 400 that is configured with optical elements 440 and not with NMR elements. Like HPP 100, apparatus 400 includes an organ chamber 410 configured to house an organ 420. However, unlike HPP 100, which includes NMR elements, apparatus 400 only includes optical elements 440 that are configured to facilitate performing optical analyses including optical coherence tomography (OCT), laser induced fluoroscopy, and optical spectroscopy on the organ 420. These optical analyses may involve directing light at the organ 420 and then receiving light back from the organ 420. Therefore, apparatus 400 includes an optical probe 444 that is configured to detect coherent light reflected from the organ 420. Even though apparatus 400 does not include NMR elements, apparatus 400 may still be placed into an MR environment and thus, in one example, apparatus 400 is constructed from MR compatible materials.

In one example, the optical elements 440 include a first fiber to deliver laser light and a second fiber to collect light from the organ 420. While a first fiber and a second fiber are described, one skilled in the art will appreciate that in one example the first fiber and the second fiber may be the same fiber. The optical elements 440 may also include an excitation source to provide the energy that is delivered through the fiber.

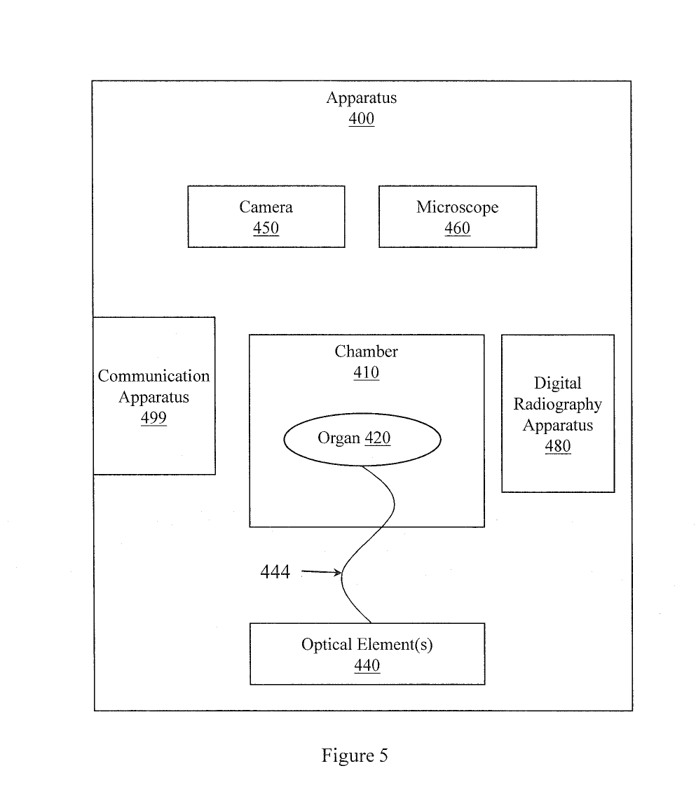

FIG. 5 illustrates an embodiment of apparatus 400 that is configured with a camera 450 and a microscope 460. While the optical elements 440 facilitate performing active operations (e.g., optical spectroscopy), the camera 450 and the microscope 460 facilitate performing passive operations (e.g., photography). FIG. 5 also illustrates apparatus 400 including a digital radiography apparatus 480, which may perform an additional active operation.

FIG. 5 also illustrates a communication apparatus 499. Communication apparatus 499 may be configured to provide raw data, viability data, images (e.g., photographs, radiographs), and so on that are available from apparatus 400. The communication apparatus may be configured to transmit the data over a telephone network, a cellular telephone network, a computer network, and so on. In one embodiment the data provided by communication apparatus 499 may be suitable for display on a cellular telephone with a graphic display (e.g., iPhone®), a personal computer, a tablet computer (e.g., iPad®), and so on.

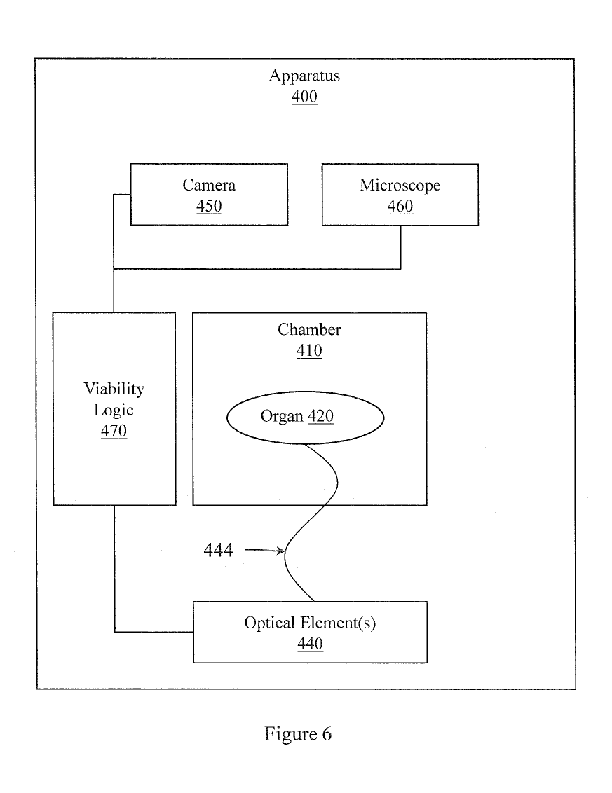

FIG. 6 illustrates an embodiment of apparatus 400 that is configured with a viability logic 470. In one embodiment, apparatus 400 may be connected to or associated with an apparatus that provides the electromagnetic energy and that also processes data received from the organ 420. However, during transport, apparatus 400 may not be connectable to the external apparatus. Therefore, in the embodiment illustrated in FIG. 6, the apparatus 400 includes a viability logic 470 that is configured to provide a signal concerning a change in the viability of the organ 420. The viability logic 470 may not be able to provide a signal that indicates that the organ 420 is or is not viable, however the viability logic 470 may be able to analyze coherent light reflected from the organ 470 and/or an image acquired from the camera 450 and/or the microscope 460 and report that the data has changed more than a threshold amount. Detecting these changes may alert the transport and/or transplant team to changing conditions that may alter workflow.

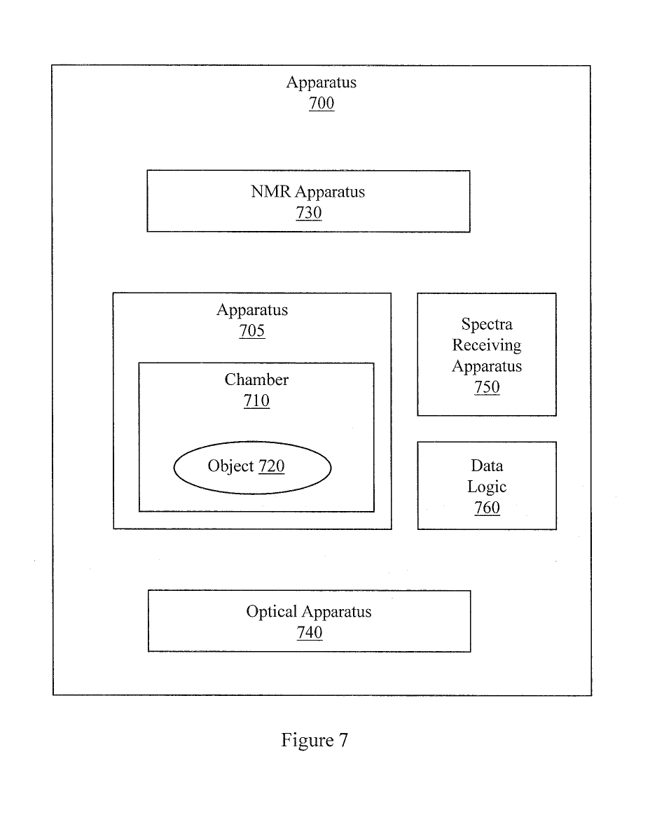

FIG. 7 illustrates an embodiment of an apparatus 700 that includes an NMR apparatus 730 configured to operate in an NMR spectrum, an optical apparatus 740 configured to operate in a non-NMR spectrum, spectra receiving apparatus 750 configured to receive spectral data in response to the NMR apparatus 730 and/or the optical apparatus 740 applying electromagnetic energy to an object 720 positioned in a perfusion apparatus 705, and a data logic 760 configured to provide object viability data based on the spectral data.

In different examples, the object 720 may be an animal tissue, a human tissue, an animal organ, and a human organ. Thus, in different examples, the perfusion apparatus 705 may be a pulsatile perfusion apparatus or a hypothermic pulsatile perfusion apparatus.

The NMR apparatus 730 is configured to apply a first energy to an object 720 positioned in the perfusion apparatus 705. The first energy is produced in accordance with a nuclear magnetic resonance (NMR) pulse sequence that is designed to excite one or more different types of nuclei (e.g., ¹H, ³¹P) in the object 720. The perfusion apparatus 705 may include an RF coil that is positioned and oriented to facilitate optimizing NMR spectroscopy of the object 720.

The apparatus 700 also includes an optical apparatus 740 configured to apply a second energy to the object 720. The second energy may be, for example, in the far infrared range, in the infrared range, in the near infrared range, in the visible range, in the ultraviolet range, and/or in the x-ray range.

While HPP 100 is the container that houses the organ, apparatus 700 can be seen as the apparatus that analyzes the object stored in HPP 100. Thus, HPP 100 may be configured to be placed in, attached to, or positioned in a known orientation and position with respect to apparatus 700.

Apparatus 700 includes a spectra receiving apparatus 750 that is configured to receive spectra data from the object 720. The spectra data is produced in response to applying the first energy and/or the second energy to the object 720. In one example, the spectra data may be acquired passively, without applying any additional energy to the object.

Apparatus 700 also includes a data logic 760 that is configured to provide objective, quantitative object viability data from the spectrum data. Data logic 760 may be, for example, a computer, a processor, a circuit, or other apparatus that computes or otherwise produces quantitative data from the spectra data received from the object 720. In different examples, the viability data may be produced in different ways. For example, the object viability data may be processed as an instantaneous measurement, as a time series, as a differential between multiple measurements, and so on. An instantaneous measurement may describe, for example, a ratio of different nuclei. A time series may be employed to describe how conditions are changing, if at all, over time. Similarly, a differential between multiple measurements may provide a range of values between which the measurements have varied. These different types of measurements may be useful to determine how the organ is changing, if at all, over time. If the organ is changing at a first slower rate, then the organ may be designated for transport to a more distant recipient while if the organ is changing at a second faster rate, then the organ may be designed for transport to a more local recipient.

Once again, to increase the confidence in the measurements, the apparatus 700 may be configured with an NMR test element and/or an optical test element that facilitate monitoring whether the NMR apparatus 730 and/or the optical apparatus 740 are functioning correctly.

In one example, the data logic 760 may even be configured to use the spectrum data to generate an image of at least a portion of the object 720.

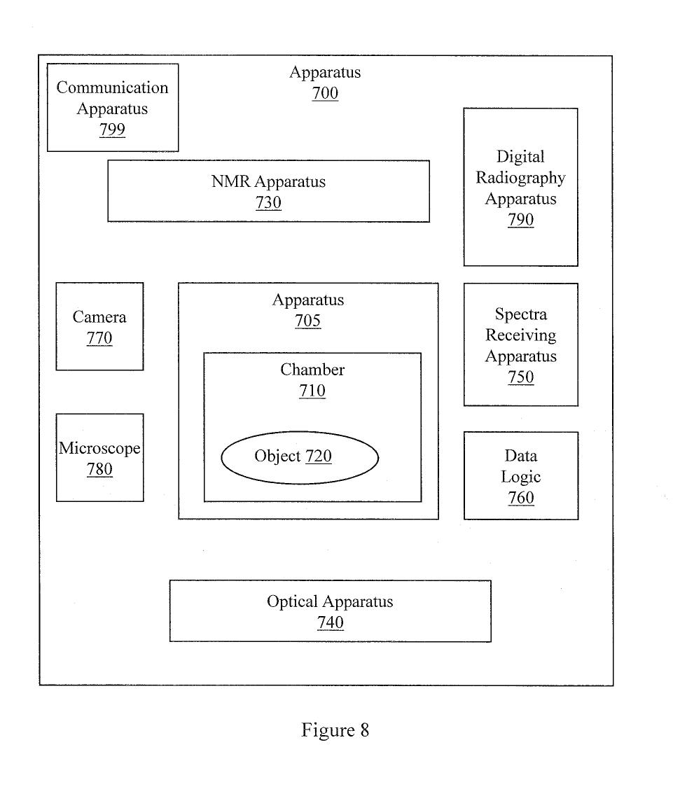

FIG. 8 illustrates an embodiment of apparatus 700 that also includes a camera 770, a microscope 780, and digital radiography equipment 790. In this embodiment, viability data may be computed using spectra data received from active operations (e.g., magnetic resonance spectroscopy, optical spectroscopy, digital radiography) and/or from photographic data received from passive operations (e.g., photography, IR imagery).

FIG. 8 also illustrates a communication apparatus 799. Communication apparatus 799 may be configured to provide raw data, viability data, images (e.g., photographs, radiographs), and so on that are available from apparatus 700. The communication apparatus may be configured to transmit the data over a telephone network, a cellular telephone network, a computer network, and so on. In one embodiment the data provided by communication apparatus 799 may be suitable for display on a cellular telephone with a graphic display (e.g., iPhone®), a personal computer, a tablet computer (e.g., iPad®), and so on.

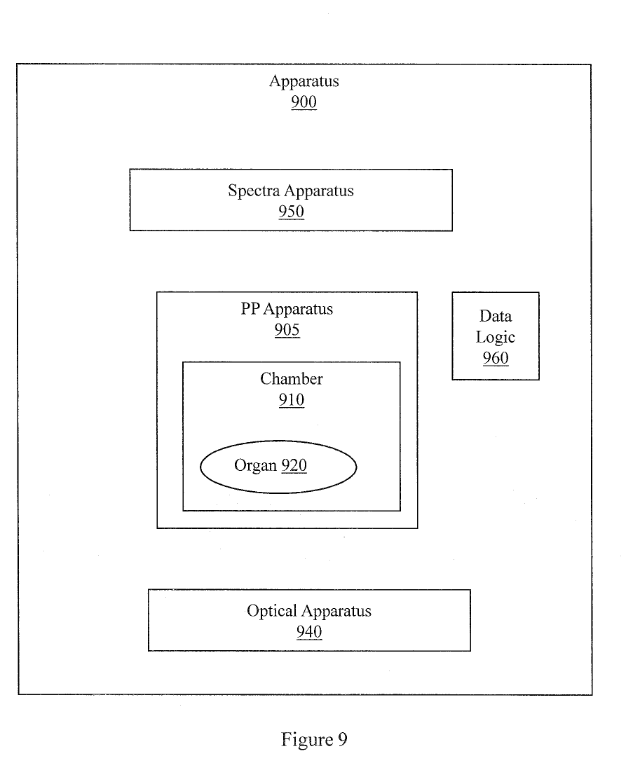

FIG. 9 illustrates an embodiment of an apparatus 900 that includes optical apparatus 940 configured to perform an optical-based analysis of an organ 920 positioned in a pulsatile perfusion apparatus 905. Performing the optical-based analysis may include applying a first energy to an organ 920 positioned in the pulsatile perfusion apparatus 905. In one example, the first energy is in the near infrared range and is sufficient to generate an optical response in the organ 920. In another example, the optical analysis (e.g., photography) may not involve applying additional energy to the object.

Apparatus 900 also includes a spectra apparatus 950 that is configured to receive spectrum data from the organ 920. After receiving the spectrum data, the spectra apparatus 950 may perform a first analysis using the spectrum data. Results of the first analysis may be provided to a data logic 960 that is configured to provide objective, quantitative organ viability data from the spectrum data.

In one example, the apparatus 900 may also include a nuclear magnetic resonance (NMR) apparatus that is configured to facilitate performing a second analysis of the organ 920. In this embodiment, the NMR apparatus is configured to apply a second energy to the organ 920. The second analysis may be, for example, magnetic resonance spectroscopy (MRS), magnetic resonance imaging (MRI), and/or other MR based analyses.

This combination embodiment may include a spectrum apparatus that is configured to facilitate performing a third analysis of the organ. The third analysis may be based, for example, on optical coherence tomography (OCT), on optical spectroscopy, on diffusive optical imaging, on microscopy, on digital radiography, IR imagery, and/or on photography.

In this embodiment, the spectra apparatus 950 is configured to perform the first, second, and third analysis, and the apparatus 900 is constructed from MR compatible, non-ferromagnetic materials.

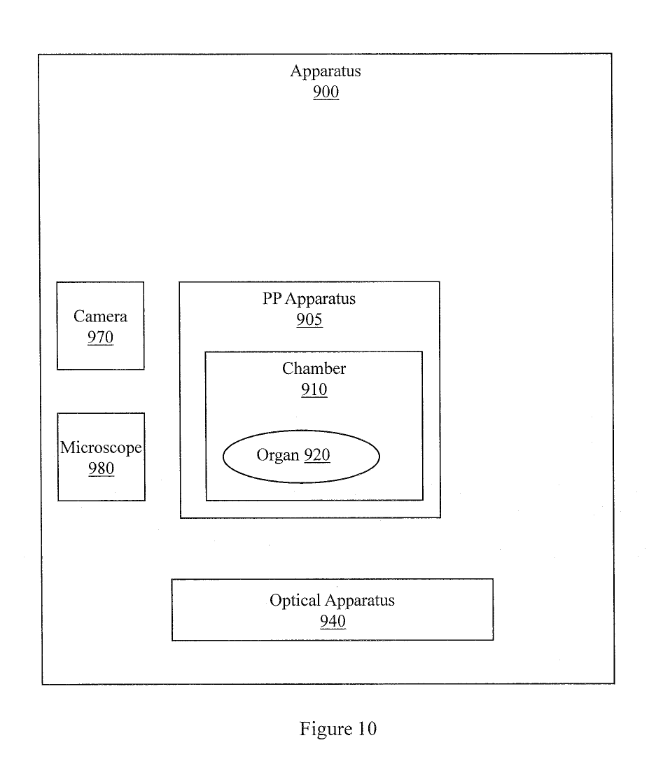

FIG. 10 illustrates an embodiment of apparatus 900 that also includes a camera 970 and a microscope 980. In this embodiment, viability may, additionally and/or alternatively, be determined from photographic or other imaging data.

More generally, this application describes an apparatus that includes a spectra logic that is configured to receive spectrum data from an object (e.g., organ, tissue) positioned in a perfusion apparatus and that is also configured to analyze object viability as a function of the spectrum data. The apparatus may include a data logic configured to provide objective, quantitative viability data from the spectrum data. The spectrum data may be NMR spectrum data and/or non-NMR spectrum data. The spectra logic may be configured to receive spectrum data from an optical probe. The apparatus may produce data and/or images. The data and/or images may be produced once, may be produced repetitively over a period of time, may be analyzed over time to produce a single viability data, and so on.

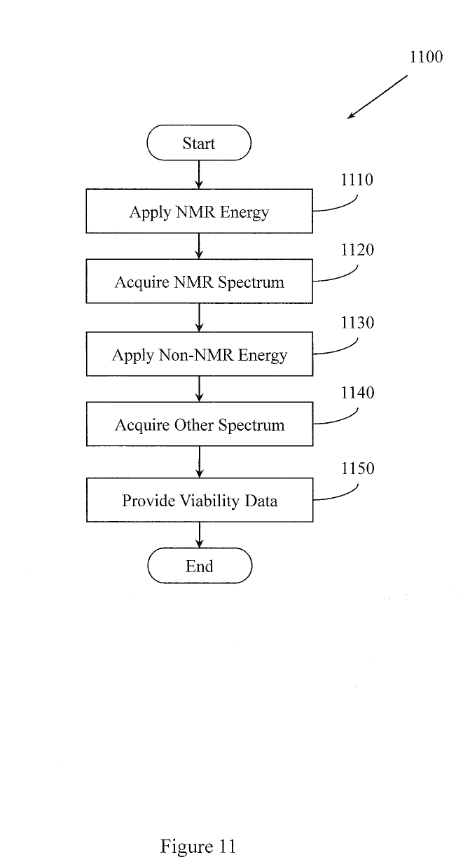

FIG. 11 illustrates a method 1100 associated with providing viability data from spectral data acquired from an object (e.g., organ, tissue) that is housed in a perfusion (e.g., pulsatile perfusion, hypothermic pulsatile perfusion) apparatus. The organ is analyzed using both an MR based approach and a non-MR based approach.

Method 1100 includes, at 1110, controlling a dedicated NMR apparatus to apply NMR electromagnetic energy to the object housed in the perfusion apparatus. The object may be, for example, an animal tissue, a human tissue, an animal organ, and a human organ. The NMR electromagnetic energy may be associated with MRI and/or MRS.

Method 1100 also includes, at 1120, acquiring NMR spectrum data from the object. The NMR spectrum data will be produced in response to applying the NMR electromagnetic energy to the object.

Method 1100 also includes, at 1130, controlling a dedicated non-NMR apparatus to apply non-NMR electromagnetic energy to the object. The non-NMR electromagnetic energy may be associated with, for example, OCT, optical spectroscopy, digital radiography, and so on.

Method 1100 also includes, at 1140, acquiring non-NMR spectrum data from the object. The non-NMR spectrum data will have been produced in response to applying the non-NMR electromagnetic energy to the object.

Method 1100 also includes, at 1150, computing a viability data from the NMR spectrum data, and the non-NMR spectrum data, and providing the viability data. The viability data may be computed, for example, by determining a ratio(s) between data values (e.g., PME peak, PI peak), by determining normalized values of data values (e.g., color), by determining the presence or absence of certain values (e.g., metabolite peaks), and so on. One skilled in the art will appreciate that the viability data may be based on spectra data identifying one or more of, mitochondrial function, ATP content, and NADH concentration.

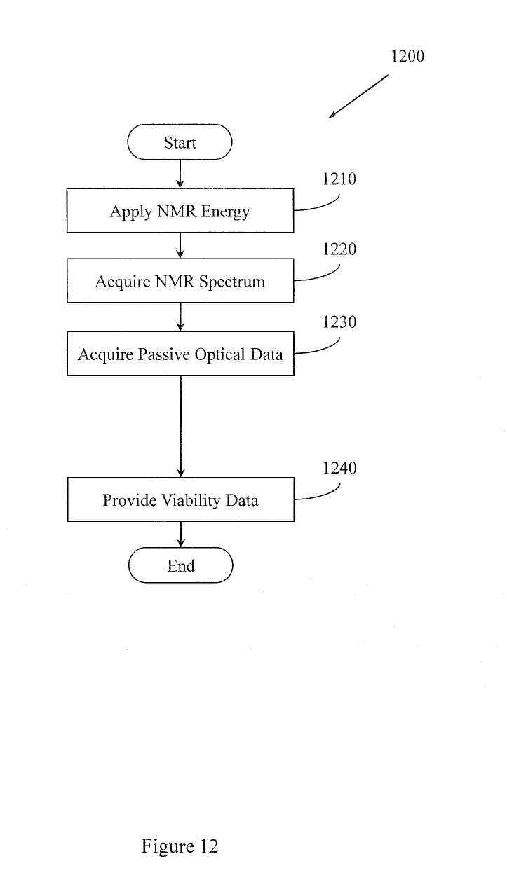

FIG. 12 illustrates a method 1200 associated with providing organ viability data from data acquired from an organ that is housed in a pulsatile perfusion apparatus. In method 1200, the organ is analyzed using both an MR based approach and a photographic approach.

Thus, method 1200 includes, at 1210, controlling a dedicated NMR apparatus to apply NMR electromagnetic energy to an object housed in a perfusion apparatus.

Method 1200 also includes, at 1220, acquiring NMR spectrum data from the object. The NMR spectrum data will be produced in response to applying the NMR electromagnetic energy.

Method 1200 also includes, at 1230, controlling a photographic apparatus to acquire photographic data from the object.

Method 1200 also includes, at 1240, computing a viability data from the NMR spectrum data and the photographic data and providing the viability data. Computing the viability data may include, for example, correlating spectra data with photographic data, interpreting photographic data in light of spectra data, interpreting spectra data in light of photographic data, and so on. For example, photographic data may reveal areas having different colors. Spectra data may reveal areas or volumes having certain ratios (e.g., PME/Pi). Computing the viability data may include producing a value as a function of both the color data and the ratio data. One skilled in the art will appreciate that there are other ways to integrate MR spectra data, non-MR spectra data, and/or photographic data.

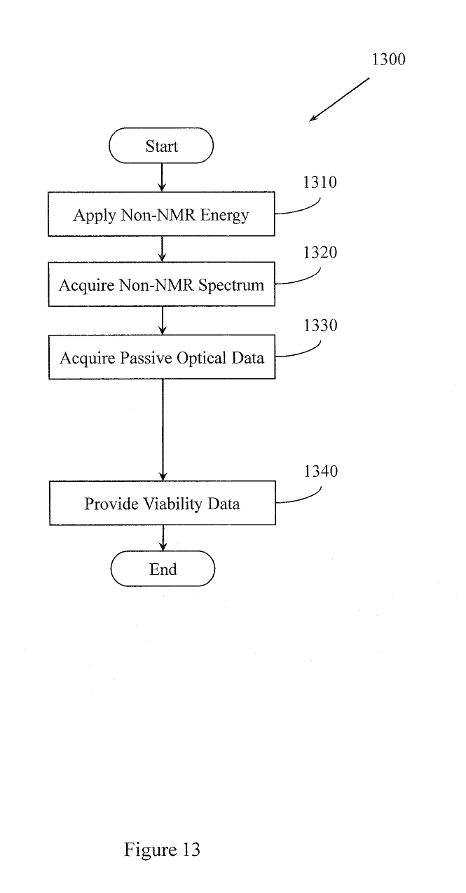

FIG. 13 illustrates a method 1300 associated with providing organ viability data from spectral and/or photographic data acquired from an organ that is housed in a pulsatile perfusion apparatus, where the organ is analyzed using one or more of, a non-MR technique, and a photographic technique.

Method 1300 includes, at 1310, controlling a dedicated non-NMR apparatus to apply non-NMR electromagnetic energy to an object housed in the perfusion apparatus. The object may be, for example, a tissue or an organ of a human or other species. The perfusion apparatus may be, for example, a pulsatile perfusion apparatus, a hypothermic perfusion apparatus, or other perfusion apparatus suitable for the type of object to be housed and perfused. The dedicated non-NMR apparatus may be, for example, an optical coherence tomography (OCT) apparatus, an optical spectroscopy apparatus, a digital radiography apparatus, and so on.

Having applied the non-NMR energy at 1310, method 1300 proceeds, at 1320, to acquire non-NMR spectrum data from the object. The non-NMR spectrum data is produced passively and/or in response to applying the non-NMR electromagnetic energy to the object.

Having acquired, for example, optical spectroscopic data at 1320, method 1300 may also include, at 1330, controlling a photographic apparatus to acquire photographic data from the object. The photographic data may be acquired from a regular camera, from a camera associated with a microscope, and from other types of cameras.

With the non-NMR spectrum data and the photographic data available, method 1300 includes, at 1340, computing and providing a viability data from the non-NMR spectrum data and the photographic data. The viability data may describe a current condition in an object (e.g., organ), a comparative condition for the object, an average condition for the object, and so on. For example, while in the control of a harvesting surgeon and pathologist, a set of benchmark measurements and photographs of a kidney to be transplanted may be acquired. Then, while the kidney is being transported in the perfusion apparatus, additional measurements may be made. If the additional measurements vary by more than a threshold amount from the benchmark measurements then a signal may be provided.

Providing the viability data may include, for example, generating a numeric output, generating an electrical signal, generating a graphic output, generating an audio output, generating a visual output, generating a color-coded output, generating a data packet for transmission on a computer network or other communication network, and so on.

To the extent that the term “includes” or “including” is employed in the detailed description or the claims, it is intended to be inclusive in a manner similar to the term “comprising” as that term is interpreted when employed as a transitional word in a claim.

While example systems, methods, and so on have been illustrated by describing examples, and while the examples have been described in considerable detail, it is not the intention of the applicants to restrict or in any way limit the scope of the appended claims to such detail. It is, of course, not possible to describe every conceivable combination of components or methodologies for purposes of describing the systems, methods, and so on described herein. Therefore, the invention is not limited to the specific details, the representative apparatus, and illustrative examples shown and described. Thus, this application is intended to embrace alterations, modifications, and variations that fall within the scope of the appended claims.

What is claimed is:

1. A hypothermic pulsatile perfusion (HPP) apparatus, comprising:
a chamber configured to house an organ;
one or more nuclear magnetic resonance (NMR) elements configured to facilitate performing a first magnetic resonance (MR) based analysis of the organ using frequencies falling within a spectral bound, the spectral bound being associated with NMR; and
one or more spectrum elements configured to facilitate performing a second, different analysis of the organ using a second set of frequencies falling outside of the spectral bound;
the apparatus being constructed from MR compatible, non-ferromagnetic materials.

2. The HPP apparatus of claim 1, the first analysis being one or more of, magnetic resonance spectroscopy (MRS), and magnetic resonance imaging (MRI).

3. The HPP apparatus of claim 1, the second analysis being one or more of, infrared imaging, optical coherence tomography (OCT), optical spectroscopy, reflectance, absorption spectroscopy, emission spectroscopy, laser-induced fluorescence, diffusive optical imaging, fluoroscopy, digital radiography, x-ray, microscopy, digital radiography, and photography.

4. The HPP apparatus of claim 1, the second analysis being an active operation comprising applying second electromagnetic energy to the organ and receiving spectrum data in response to applying the second electromagnetic energy to the organ.

5. The HPP apparatus of claim 4, the second set of frequencies being in one or more of, the far infrared range, the infrared range, the near infrared range, the visible range, the ultraviolet range, and x-ray range.

6. The HPP apparatus of claim 1, where the second analysis is a passive operation comprising receiving image data from the organ.

7. The HPP apparatus of claim 1, comprising:
a sterile, disposable inner liner configured to house the organ in the chamber.

8. The HPP apparatus of claim 7, the inner liner being configured to hold the organ in a substantially constant position and orientation with respect to one or more of, the NMR elements, and the spectrum elements.

9. The HPP apparatus of claim 7, the inner liner being configured to house the organ in a liquid solution.

10. The HPP apparatus of claim 1, the one or more spectrum elements comprising:
an optical probe configured to detect coherent light reflected from the organ, the optical probe being configured to facilitate performing one or more of, optical coherence tomography (OCT), and optical spectroscopy on the organ, the optical probe being constructed from MR compatible, non-ferromagnetic materials.

11. The HPP apparatus of claim 10, the optical probe being positioned to remain at least a predetermined distance away from the organ.

12. The HPP apparatus of claim 10, the optical probe being positioned to be placed within the organ for interstitial analysis.

13. The HPP apparatus of claim 1, comprising one or more of, an NMR test element configured to facilitate acquiring test data for assessing operation of the NMR elements, and a spectrum test element configured to facilitate acquiring test data for assessing operation of the spectrum elements.

14. The HPP apparatus of claim 1, the MR based analysis of the organ and the second analysis of the organ being configured to provide information concerning one or more of, mitochondrial function of the organ, ATP content of the organ, ADP content of the organ, NADH concentration in the organ, a ¹H peak, and a ³¹P peak.

15. The HPP apparatus of claim 1, the first analysis and the second analysis being configured to provide data concerning one or more of, perfusion, disease detection, and cancer detection.

16. The HPP apparatus of claim 1, comprising a communication apparatus configured to provide one or more of, raw data, viability data, and imagery.

17. The HPP of claim 16, the communication apparatus being one of, a cellular telephone communication apparatus, a telephone communication apparatus, and a computer networking apparatus.

18. The HPP of claim 16, the raw data, viability data, and imagery being suitable for display on one or more of, a cellular telephone with a graphic display, a personal computer, and a tablet computer.

19. A hypothermic pulsatile perfusion (HPP) apparatus, comprising:
an organ chamber configured to house an organ;
one or more optical elements configured to facilitate performing one or more of, optical coherence tomography (OCT), laser induced fluoroscopy, infrared imaging, and optical spectroscopy on the organ; and
an optical probe configured to detect coherent light reflected from the organ;
the HPP being constructed from MR compatible materials.

20. The HPP of claim 19, comprising one or more of, a camera, an infrared camera, a microscope, and a digital radiography apparatus.

21. The HPP of claim 20, comprising a viability logic configured to provide a signal concerning a change in the viability of the organ as a function of analyzing one or more of, the coherent light reflected from the organ, and an image acquired from one or more of, the camera, the infrared camera, the digital radiography apparatus, and the microscope.

22. The HPP apparatus of claim 19, where the optical probe is configured to facilitate performing one or more of, optical coherence tomography (OCT), and optical spectroscopy on the organ, the optical probe being constructed from MR compatible, non-ferromagnetic materials.

23. The HPP apparatus of claim 19, where the optical elements comprise:
a first fiber to deliver laser light, and
an excitation source;
and
where the optical probe comprises a second fiber to collect light from the organ.

24. The HPP apparatus of claim 23, where the first fiber and the second fiber are the same fiber.

25. An apparatus, comprising:
an NMR apparatus configured to apply a first energy to an object positioned in a perfusion apparatus, the first energy being produced in accordance with a nuclear magnetic resonance (NMR) pulse sequence designed to excite one or more nuclei in the object, the perfusion apparatus comprising an RF coil positioned and oriented to facilitate optimizing NMR spectroscopy of the object;
an optical apparatus configured to apply a second energy to the object positioned in the perfusion apparatus;
a spectra receiving apparatus configured to receive spectrum data from the object, the spectrum data being produced in response to applying at least one of, the first energy, and the second energy to the object; and
a data logic configured to provide objective, quantitative object viability data from the spectrum data.

26. The apparatus of claim 25, the second energy being in one or more of, the far infrared range, the infrared range, the near infrared range, the visible range, the ultraviolet range, and x-ray range.

27. The apparatus of claim 25, where the object viability data is processed as at least one of, an instantaneous measurement, a time series measurement, and a differential between multiple measurements, where the measurements concern one or more of, mitochondrial function of the organ, ATP content of the organ, ADP content of the organ, NADH concentration in the organ, a ¹H peak, and a ³¹P peak.

28. The apparatus of claim 25, where the data logic is configured to generate an image of at least a portion of the object from the spectrum data.

29. The apparatus of claim 25, where the data logic is configured to to generate an image of at least a portion of the object from the spectrum data and to generate at least one of, an instantaneous measurement, a time series, and a differential between multiple measurements.

30. The apparatus of claim 25, comprising at least one of, an NMR test element, and an optical test element, where the NMR test element is configured to facilitate monitoring whether the NMR apparatus is functioning correctly, and the optical test element is configured to facilitate monitoring whether the optical apparatus is functioning correctly.

31. The apparatus of claim 25, the object being one of, an animal tissue, a human tissue, an animal organ, and a human organ.

32. The apparatus of claim 25, where perfusion apparatus is one of, a pulsatile perfusion apparatus, and a hypothermic pulsatile perfusion apparatus.

33. The apparatus of claim 25, comprising a communication apparatus configured to provide one or more of, raw data, viability data, and imagery.

34. The apparatus of claim 33, the communication apparatus being one of, a cellular telephone communication apparatus, a telephone communication apparatus, and a computer networking apparatus.

35. The HPP of claim 33, the raw data, viability data, and imagery being suitable for display on one or more of, a cellular telephone with a graphic display, a personal computer, and a tablet computer.

36. An apparatus, comprising:
an optical apparatus configured to apply a first energy to an organ positioned in a pulsatile perfusion (PP) apparatus;
a spectra apparatus configured to receive spectrum data from the organ and to perform a first analysis, the spectrum data being produced in response to applying the first energy to the organ; and
a data logic configured to provide objective, quantitative organ viability data from the spectrum data.

37. The apparatus of claim 36, the first energy being in the near infrared range.

38. The apparatus of claim 36, the first energy being sufficient to generate an optical response in the organ.

39. The apparatus of claim 36, comprising:
a nuclear magnetic resonance (NMR) apparatus configured to facilitate performing a second analysis of the organ, where the NMR apparatus is configured to apply a second energy to the organ, the second analysis being one or more of, magnetic resonance spectroscopy (MRS), and magnetic resonance imaging (MRI); and
a spectrum apparatus configured to facilitate performing a third analysis of the organ, the third analysis being one or more of, optical coherence tomography (OCT), optical spectroscopy, diffusive optical imaging, digital radiography, microscopy, photography, and infrared imaging; and
where the spectra apparatus is configured to perform the first, second, and third analysis, and the apparatus is constructed from MR compatible, non-ferromagnetic materials.

40. A method, comprising:
controlling a dedicated NMR apparatus to apply NMR electromagnetic energy to an object housed in a perfusion apparatus;
acquiring NMR spectrum data from the object, the NMR spectrum data having been produced in response to applying the NMR electromagnetic energy;
controlling a dedicated non-NMR apparatus to apply non-NMR electromagnetic energy to the object;
acquiring non-NMR spectrum data from the object, the non-NMR spectrum data having been produced in response to applying the non-NMR electromagnetic energy;
computing a viability data from the NMR spectrum and the non-NMR spectrum data; and
providing the viability data.

41. The method of claim 40, the object being one of, an animal tissue, a human tissue, an animal organ, and a human organ and the viability data concerning one or more of, mitochondrial function of the organ, ATP content of the organ, ADP content of the organ, NADH concentration in the organ, a ¹H peak, and a ³¹P peak.

42. The method of claim 40, the dedicated non-NMR apparatus being one of, an optical coherence tomography (OCT) apparatus, and an optical spectroscopy apparatus.

43. A method, comprising:
controlling a dedicated NMR apparatus to apply NMR electromagnetic energy to an object housed in a perfusion apparatus;
acquiring NMR spectrum data from the object, the NMR spectrum data having been produced in response to applying the NMR electromagnetic energy;
controlling a photographic apparatus to acquire photographic data from the object;
computing a viability data from the NMR spectrum data and the photographic data; and
providing the viability data.

44. The method of claim 43, the object being one of, an animal tissue, a human tissue, an animal organ, and a human organ, the perfusion apparatus being one of, a pulsatile perfusion apparatus, and a hypothermic pulsatile perfusion apparatus, and the viability data concerning one or more of, mitochondrial function of the organ, ATP content of the organ, ADP content of the organ, NADH concentration in the organ, a ¹H peak, and a ³¹P peak.

45. A method, comprising:
controlling a photographic apparatus to acquire photographic data from an object housed in a perfusion apparatus;
computing viability data from the photographic data; and
providing the viability data.

46. The method of claim 45, the object being one of, an animal tissue, a human tissue, an animal organ, and a human organ, the perfusion apparatus being one of, a pulsatile perfusion apparatus, and a hypothermic pulsatile perfusion apparatus, and the viability data concerning one or more of, mitochondrial function of the organ, ATP content of the organ, ADP content of the organ, NADH concentration in the organ, a ¹H peak, and a ³¹P peak.

47. The method of claim 45, comprising:
controlling a dedicated non-NMR apparatus to apply non-NMR electromagnetic energy to the object, the dedicated non-NMR apparatus being one of, an optical coherence tomography (OCT) apparatus, and an optical spectroscopy apparatus;
acquiring non-NMR spectrum data from the object, the non-NMR spectrum data having been produced in response to applying the non-NMR electromagnetic energy to the object; and
computing viability data from the photographic data and the non-NMR data.
